(19) United States
(12) Patent Application Publication
(10) Pub. No.: US 2009/0288870 A1
(43) Pub. Date: Nov. 26, 2009

(54) WIRING SUBSTRATE AND METHOD OF MANUFACTURING THE SAME

(75) Inventors: Hitoshi KONDO, Nagano (JP); Tomoyuki Shimodaira, Nagano (JP); Tadashi Kodaira, Nagano (JP)

Correspondence Address: KRATZ, QUINTOS & HANSON, LLP, 1420 K Street, N.W., Suite 400, WASHINGTON, DC, 20005, US

(73) Assignee: SHINKO ELECTRIC INDUSTRIES CO., LTD., Nagano-shi (JP)

(21) Appl. No.: 12/469,952

(22) Filed: May 21, 2009

(30) Foreign Application Priority Data
May 25, 2008 (JP) 2008-137979
Aug. 1, 2008 (JP) 2008-199728

(51) Int. Cl. H05K 1/11; H01B 13/00; C25D 5/02

(52) U.S. Cl. 174/261; 216/18; 205/125

(57) ABSTRACT

A method of manufacturing a wiring substrate of the present invention, includes a step of forming a first wiring layer on an underlying layer, a step of forming a stacked body in which a protection layer is provided on an insulating layer, on the first wiring layer, a step of forming a via hole reaching the first wiring layer by processing the protection layer and the insulating layer, a step of roughening a side surface of the via hole by applying a desmear process to an inside of the via hole while using the protection layer as a mask, a step of removing the protection layer, and a step of forming a second wiring layer, which is connected to the first wiring layer via the via hole, on the insulating layer. The second wiring layer may be formed after the surface of the insulating layer is roughened, or the second wiring layer may be formed without roughening of the surface of the insulating layer.

### CROSS-REFERENCE TO RELATED APPLICATIONS

This application is based on and claims priority of Japanese Patent Application No. 2008-137979 filed on May 25, 2008 and Japanese Patent Application No. 2008-199728 filed on Aug. 1, 2008, the entire contents of which are incorporated herein by reference.

### BACKGROUND OF THE INVENTION

1. Field of the Invention

The present invention relates to a wiring substrate and a method of manufacturing the same and, more particularly, a wiring substrate and a method of manufacturing the same, which is applicable to a substrate of a semiconductor package.

2. Description of the Related Art

In the prior art, there is the build-up wiring board having the multilayer wiring in which a wiring layer and a resin layer are formed alternately on a substrate. In the method of manufacturing the build-up wiring board in the prior art, as shown in FIG. 1A, first, a first wiring layer 200 is formed on a substrate 100. Then, as shown in FIG. 1B, an interlayer insulating layer 300 is formed by pressure-bonding a resin film onto the first wiring layer 200.

Then, as shown in FIG. 1C, the interlayer insulating layer 300 is processed by the laser beam machining. Thus, a via hole VH having a depth reaching the first wiring layer 200 is formed.

Then, as shown in FIG. 1D, the desmear process is applied to the inside of the via hole VH by using a potassium permanganate solution, or the like. Thus, a resin smear remaining on a bottom of the via hole VH is cleaned. At this time, unevenness (concave-convex surface) is formed on a side surface of the via hole VH and a surface of the interlayer insulating layer 300 by a potassium permanganate solution, thereby those surfaces are roughened.

Then, second wiring layers connected to the first wiring layer 200 via the via hole VH are formed on the interlayer insulating layer 300 by the semi-additive process. For more detailed explanation, as shown in FIG. 2A, first, a seed layer 420 made of copper is formed on the inner surface of the via hole VH and the interlayer insulating layer 300 by the electroless plating. By roughening the surface of the interlayer insulating layer 300, the seed layer 420 can be formed on the interlayer insulating layer 300 with good adhesion by an anchor effect (fragmental enlarged sectional view in FIG. 2A).

Then, as shown in FIG. 2B, a plating resist 500 in which opening portions 500a are provided in portions where the second wiring layers are arranged is formed on the seed layer 420. Then, a copper plating layer 440 is formed in the via hole VH and the opening portions 500a of the plating resist 500 by the electroplating using the seed layer 420 as a plating power feeding path. Then, as shown in FIG. 2C, the plating resist 500 is removed to expose the seed layer 420.

Then, as shown in FIG. 2D, the seed layer 420 is etched by the wet etching while using the copper plating layer 440 as a mask. Thus, second wiring layers 400 each composed of the seed layer 420 and the copper plating layer 440 are obtained.

In Patent Literature 1 (Patent Application Publication (KOKAI) 2000-286559), it is set forth that amide groups are produced by applying a reforming process to a surface of an insulating resin substrate, thereby a metal oxide layer whose reduction potential is lower than copper is formed, and then fine copper wirings whose thickness is several tens micrometer or less and whose adhesion is high are formed by depositing the copper.

In Patent Literature 2 (Patent Application Publication (KOKAI) 2004-202517), it is set forth that a surface of a processed member such as a multi-layered build-up substrate, or the like is processed by the laser in a state that an aberration eliminating sheet is provided thereon, and then the aberration eliminating sheet is removed, whereby a shape collapse of the processed member can be prevented and a processing shape with high aspect ratio can be obtained.

In the above-mentioned prior art, upon applying the desmear process to the inside of the via hole VH (FIG. 1D), if such desmear process is applied sufficiently such that reliability of the via connection can be obtained, a surface roughness (Ra) of the interlayer insulating layer 300 becomes 400 to 1000 nm. Thus, unevenness of the surface thereof becomes considerably large.

In the above step of etching the seed layer 420 by the semi-additive process, there is such a tendency that an etching residue occurs more easily as unevenness of the surface of the interlayer insulating layer 300 is increased larger.

Therefore, as shown in FIG. 3A, a considerable overetching is needed in etching the seed layer 420 in the prior art. As a result, an amount of undercut of the seed layer 420 whose etching rate is high is increased, and a finished line width of the second wiring layer 400 is easy to become thin.

Thus, as shown in FIG. 3B, when particularly a line:space of the second wiring layer 400 becomes smaller than 15:15 μm or less, a rate of an amount of undercut of the seed layer 420 to a designed width of the second wiring layer 400 is increased. Therefore, a line width becomes considerably thinner than a design specification, and furthermore the pattern jump (pattern disappearance) of the wiring layer is caused.

In this manner, in the prior art, when the line:space of the wiring layer is less than 15:15 μm in a design rule, it is difficult to form the wiring layer according to a design specification with good yield.

### SUMMARY OF THE INVENTION

It is an object of the present invention to provide a wiring substrate and a method of manufacturing the same, capable of responding to miniaturization (line:space=15:15 μm or less) of a wiring layer, and also obtaining sufficient adhesion between the wiring layer and an underlying insulating layer.

The present invention is concerned with a method of manufacturing a wiring substrate, which includes a step of forming a first wiring layer on an underlying layer; a step of forming a stacked body in which a protection layer is provided on an insulating layer, on the first wiring layer; a step of forming a via hole reaching the first wiring layer, by processing the protection layer and the insulating layer; a first roughening step of roughening a side surface of the via hole, by applying a desmear process to an inside of the via hole while using the protection layer as a mask; a step of exposing a surface of the insulating layer by removing the protection layer; and a step of forming a second wiring layer, which is connected to the first wiring layer via the via hole, on the insulating layer.

In the present invention, first, the stacked body in which the interlayer insulating layer and the protection layer are stacked on the first wiring layer is formed, and then via holes each reaching the first wiring layer are formed by processing the stacked body. Then, the desmear process is applied to the inside of the via holes while using the protection layer as a mask to roughen the side surface of the via holes (first roughening process step). In the first roughening process step, since the insulating layer is processed to be covered with the protection layer, the surface of the insulating layer can be kept in a smooth state even though desmear process is applied sufficiently. Then, the surface of the insulating layer is exposed by removing the protection layer.

Then, in one preferred mode of the present invention, the surface of the insulating layer is roughened by a second roughening step. In this mode, the insulating layer is covered with the protection layer when the desmear process is applied in the first roughening process step, and then the surface roughening of the insulating layer is executed in the second roughening process step after the protection layer is removed. In this manner, the desmear process (roughening process) of the via hole and the surface roughening of the insulating layer are executed by the separate step respectively. Therefore, the surface of the insulating layer can be adjusted to a desired roughness, and such a situation can be avoided that excessive unevenness is formed.

By employing such approach, the surface of the insulating layer can be adjusted to an adequate surface roughness that can achieve both the fine processing and the good adhesion. Therefore, when particularly the second wiring layer connected to the first wiring layer via the via hole is formed on the insulating layer by the semi-additive process, an amount of overetching of the seed layer can be suppressed. As a result, the fine wiring layer (for example, line:space=15:15 μm or less) can be formed with good yield.

Besides, the desmear process is applied sufficiently to the inside of the via hole by the first roughening process (the first plasma process). Therefore, satisfactory reliability of the via connection can be ensured.

Also, in another preferred mode of the present invention, after the step of exposing the surface of the insulating layer by removing the protection layer, the second wiring layer is formed on the insulating layer without roughening the surface of the insulating layer. In the case of this mode, for example, the insulating layer is formed of a resin in which fillers are dispersed with the content percentage of 30 to 70 wt %, and a metal layer is used as the protection layer. Then, the resin is cured by the thermal treatment in a state that the resin is covered with the meta layer, and constitutes the insulating layer. Then, the insulating layer whose surface roughness (Ra) is small and whose adhesion to the wiring layer is high can be obtained by removing the metal layer.

Also, the present invention is concerned with a wiring substrate, which includes a first wiring layer; an insulating layer formed on the first wiring layer; a via hole provided in the insulating layer to reach the first wiring layer; and a second wiring layer formed on the insulating layer and connected to the first wiring layer via the via hole; wherein a surface roughness (Ra) of the insulating layer is set lower than a surface roughness (Ra) of a side surface of the via hole.

By employing the above method of manufacturing the wiring substrate, a surface roughness (Ra) of the insulating layer and a surface roughness (Ra) of a side surface of the via hole can be set independently to the optimum value respectively. In the wiring substrate of the present invention, a surface roughness (Ra) of the insulating layer is set lower than a surface roughness (Ra) of a side surface of the via hole.

In addition, as explained in the above manufacturing method, the adhesion of the insulating layer to the wiring layer can be increased highly while keeping the surface roughness (Ra) of the insulating layer small. As a result, the fine wiring layer can be formed on the insulating layer with good yield, the high reliability of the via connection can be obtained, and the high-performance wiring substrate whose electric characteristics are excellent can be manufactured.

As described above, the present invention can respond to the miniaturization (line:space=15:15 μm or less) of the wiring layer, and also sufficient adhesion between the wiring layer and the underlying insulating layer can be obtained.

### BRIEF DESCRIPTION OF THE DRAWINGS

FIGS. 1A to 1D are sectional views (#1) showing a method of manufacturing a wiring substrate in the prior art;

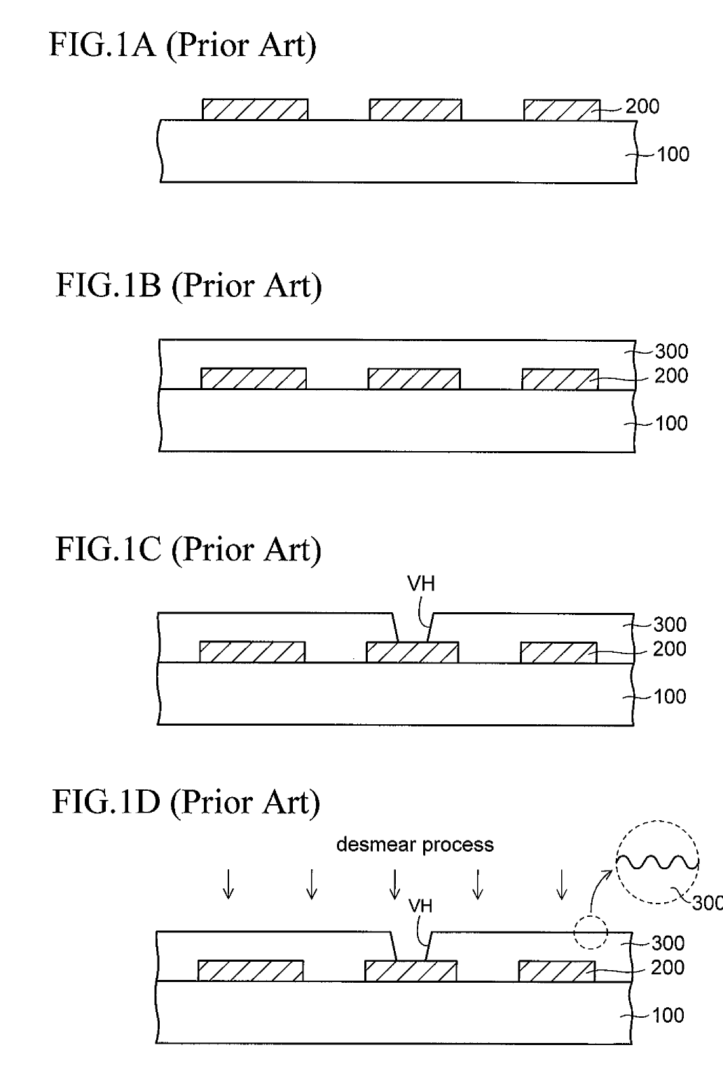

FIGS. 2A to 2D are sectional views (#2) showing the method of manufacturing the wiring substrate in the prior art;

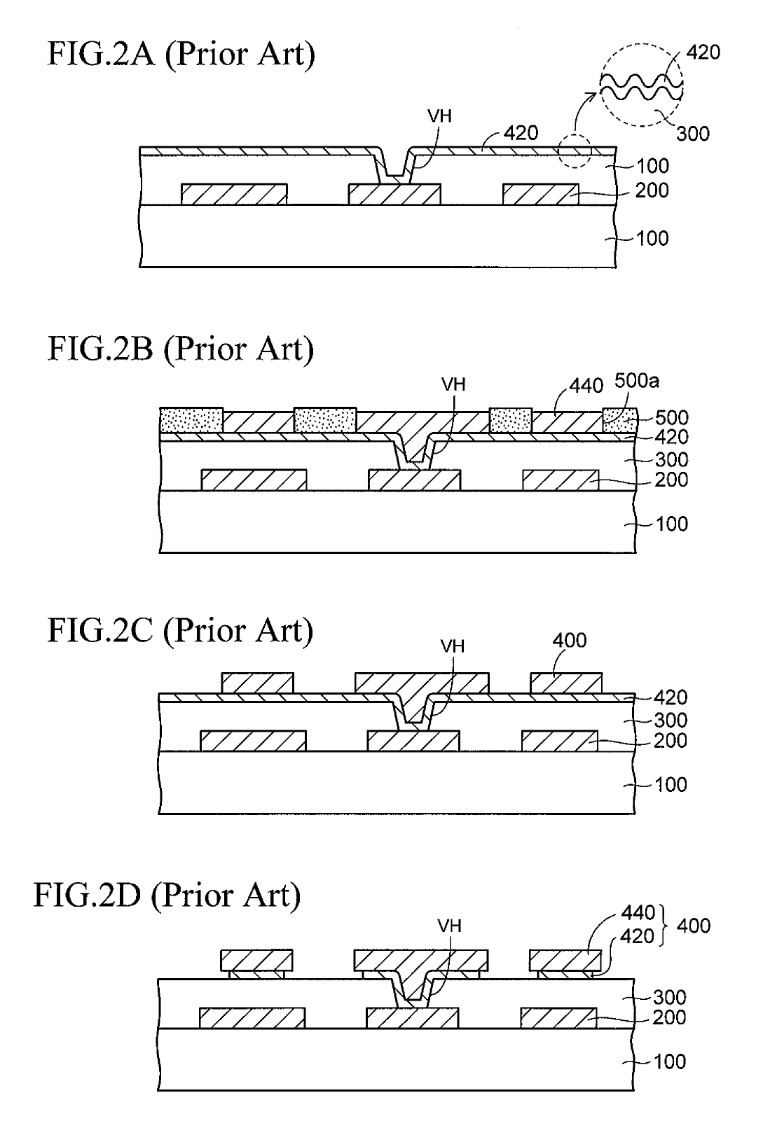

FIGS. 3A and 38 are sectional views showing the problem in the method of manufacturing the wiring substrate in the prior art;

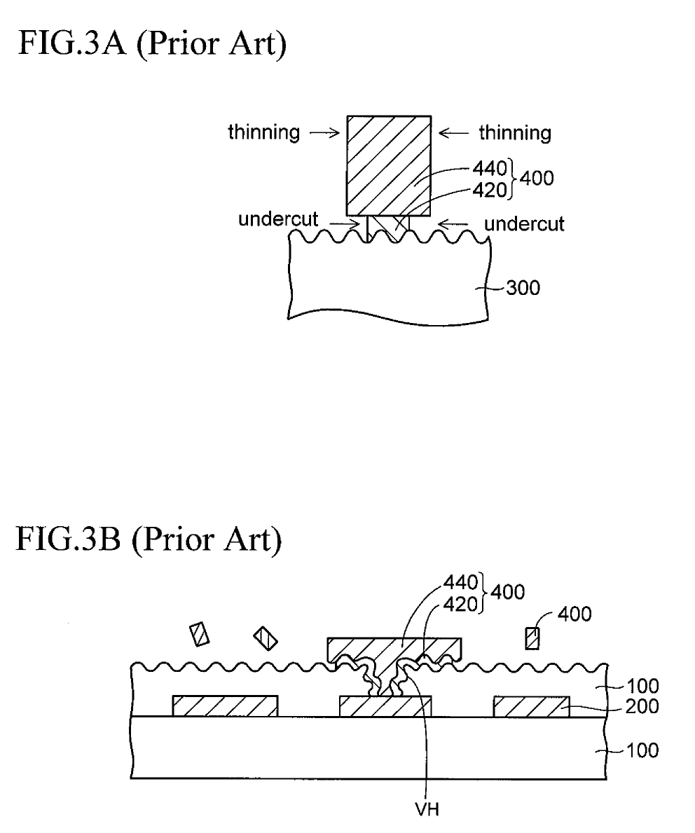

FIGS. 4A to 4C are sectional views (#1) showing a method of manufacturing a wiring substrate according to a first embodiment of the present invention;

FIGS. 5A to 5C are sectional views (#2) showing the method of manufacturing the wiring substrate according to the first embodiment of the present invention;

FIGS. 6A to 6C are sectional views (#3) showing the method of manufacturing the wiring substrate according to the first embodiment of the present invention;

FIGS. 7A to 7C are sectional views (#4) showing the method of manufacturing the wiring substrate according to the first embodiment of the present invention;

FIGS. 8A to 8C are sectional views (#1) showing a method of manufacturing a wiring substrate according to a second embodiment of the present invention;

FIGS. 9A to 9C are sectional views (#2) showing the method of manufacturing the wiring substrate according to the second embodiment of the present invention;

FIGS. 10A to 10C are sectional views (#3) showing the method of manufacturing the wiring substrate according to the second embodiment of the present invention;

FIGS. 11A and 11B are sectional views (#4) showing the method of manufacturing the wiring substrate according to the second embodiment of the present invention; and

FIG. 12 is a sectional view showing an example of the wiring substrate according to the second embodiment of the present invention.

### DETAILED DESCRIPTION OF THE PREFERRED EMBODIMENTS

Embodiments of the present invention will be explained with reference to the accompanying drawings hereinafter.

### First Embodiment

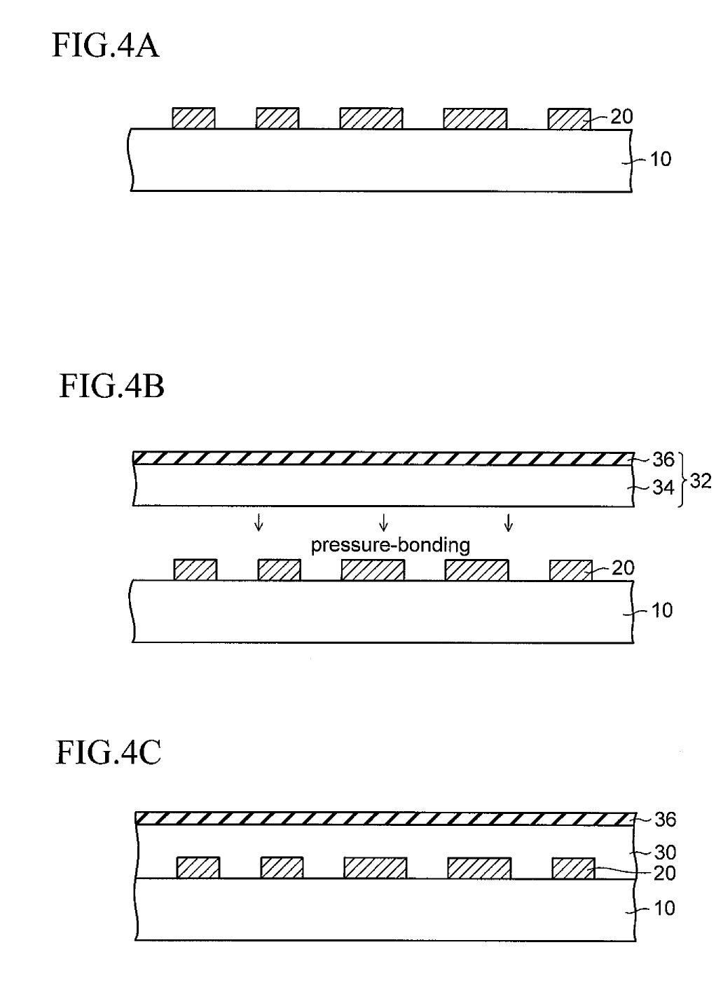

FIGS. 4A to 4C, FIGS. 5A to 5C, FIGS. 6A to 6C, and FIGS. 7A to 7C are sectional views showing a method of manufacturing a wiring substrate according to a first embodiment of the present invention. In the method of manufacturing the wiring substrate according to the first embodiment, as shown in FIG. 4A, first, a first wiring layer 20 made of copper, or the like and shaped into a pattern is formed on a substrate 10. As the method of forming the first wiring layer 20, various methods such as the semi-additive process described later, and the like can be employed.

As an underlying layer on which the first wiring layer 20 is formed, the substrate 10 (glass epoxy resin, or the like) is illustrated. In this case, an insulating layer formed on the substrate 10, or the like may be employed. As the substrate 10, either a rigid type or a flexible type may be employed.

Then, as shown in FIG. 4B, a film with protection layer 32 in which a protection layer 36 is provided on a resin film 34 is prepared. The resin film 34 is formed of an epoxy resin, a polyimide resin, or the like. The protection layer 36 is formed of a PET (polyethylene terephthalate) film, a resist, a metallic foil such as a copper foil, an aluminum foil, or the like. The protection layer 36 is adhered temporarily such that this layer can be peeled easily from the resin film 34.

Then, the first wiring layer 20 is covered with the resin film 34 by thermal pressure-bonding a surface of the resin film 34 of the film with protection layer 32 onto the substrate 10. Then, as shown in FIG. 4C, an interlayer insulating layer 30 is obtained by curing the film with protection layer 32 by means of the heat treatment. Accordingly, the first wiring layer 20 is covered with the interlayer insulating layer 30, and thus the protection layer 36 is formed on the interlayer insulating layer 30.

As described later, the protection layer 36 is provided so as to protect the interlayer insulating layer 30 such that, in applying the desmear process to the inside of the via hole by using the plasma, unnecessary unevenness (concave-convex surface) is not produced on the surface of the interlayer insulating layer 30. Also, the protection layer 36 has a function of protecting the interlayer insulating layer 30 such that, in forming the interlayer insulating layer 30 by pressure-bonding the resin film 34, the damage of the interlayer insulating layer 30 is not caused.

In the above mode, as a preferred example, the film with protection layer 32 is pressure-bonded on the first wiring layer 20. In this case, a stacked body formed by stacking sequentially the insulating layer and the protection layer may be formed on the first wiring layer 20. That is, the interlayer insulating layer 30 may be formed on the first wiring layer 20 by pressure-bonding the resin film, or the like, and then the protection layer 36 may be adhered temporarily onto the interlayer insulating layer 30 peelably.

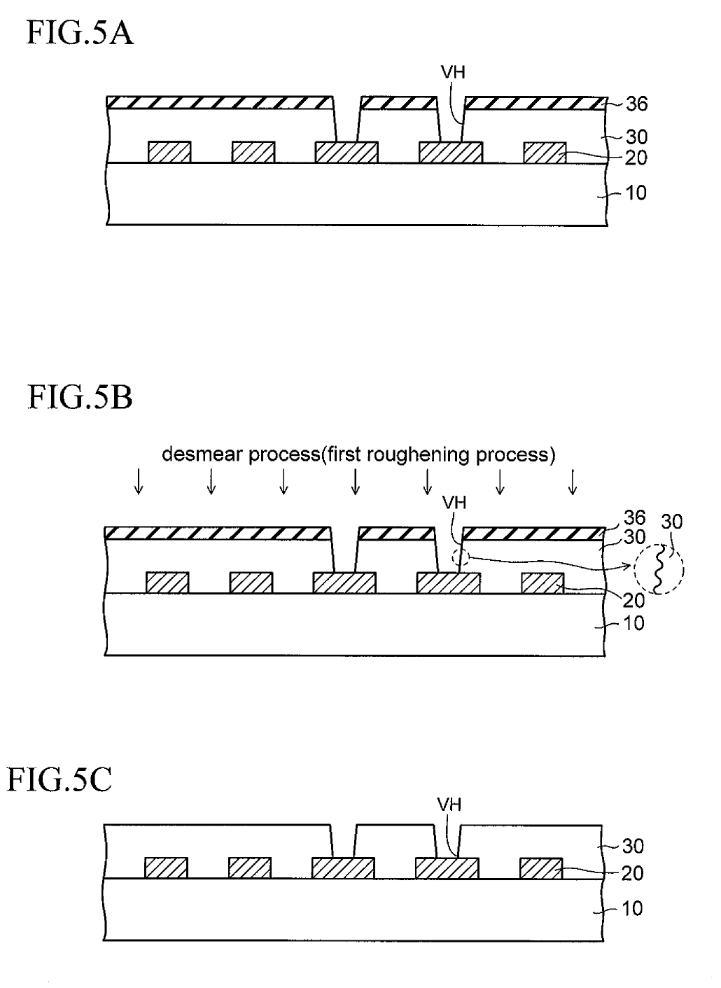

Then, as shown in FIG. 5A, the protection layer 36 and the interlayer insulating layer 30 are processed by the laser. Thus, via holes VH each having a depth reaching the first wiring layer 20 are formed. Otherwise, the via holes VH may be formed by the drilling, the anisotropic dry etching (RIE, or the like), or the like.

Then, as shown in FIG. 5B, the desmear process is applied to the inside of the via holes VH by processing the inside of the via holes VH by means of the first plasma while using the protection layer 36 as a mask (first roughening process step). Accordingly, the resin smear remaining in the inside of the via holes VH is cleaned. At the same time, side surfaces of the via holes VH are processed by the plasma and are roughened (fragmental enlarged view of FIG. 5B). Preferably, a surface roughness (Ra) of the side surfaces of the via holes VH is set to 100 to 600 nm.

In the present embodiment, the desmear process is applied to the inside of the via holes VH by the plasma while using the protection layer 36 as a mask. Therefore, the surface of the interlayer insulating layer 30 is protected from the plasma by the protection layer 36. As a result, even when the desmear process is applied sufficiently to the inside of the via holes VH, the surface of the interlayer insulating layer 30 is not affected at all and is kept in a smooth state.

As the gas used in the first plasma process (the first roughening process), any gas selected from a group consisting of a gas containing fluorine atoms such as CF₄ (carbon tetrafluoride), or the like, a gas containing chlorine atoms such as Cl₂ (chlorine), or the like, a gas containing bromine atoms such as HBr (hydrogen bromide), or the like, a rare gas such as He (helium), Ar (argon), Xe (xenon), or the like, O₂ (oxygen), H₂O (water), H₂ (hydrogen), N₂ (nitrogen), and NH₃ (ammonia), or a mixed gas prepared by combining two gases or more selected from above group is used. As an example of the preferred gas, a mixed gas prepared by adding O₂, N₂, or the like to CF₄ is employed.

The plasma process is executed in the dry etching equipment. As the etching system, the anisotropic dry etching (RIE, or the like) may be employed, or the isotropic dry etching may be employed.

The desmear process (roughening process) step applied to the inside of the via holes VH may be executed by the wet etching process in addition to the above plasma process. In the desmear process executed by the wet etching, the surface of the interlayer insulating layer 30 (insulating resin) is etched by a permanganate-based solution (as a preferred example, a potassium permanganate solution), and is roughened. In addition to the permanganate-based solution, various etchants (chemicals) can be employed if such etchants can roughen the surface of the insulating resin.

Then, if necessary, the inside of the via holes VH is rinsed by the ultrasonic water washing. Then, as shown in FIG. 5C, the surface of the interlayer insulating layer 30 is exposed by removing the protection layer 36. When the PET film, the copper foil, or the aluminum foil is used as the protection layer 36, such layer is removed by peeling from the peripheral portion thereof. When the resist is used as the protection layer 36, such layer is removed by the resist stripper or the dry ashing.

As described above, in the first plasma process (the first roughening process), the interlayer insulating layer 30 is protected from the plasma by the protection layer 36, and thus the exposed surface of the interlayer insulating layer 30 is kept as a smooth surface.

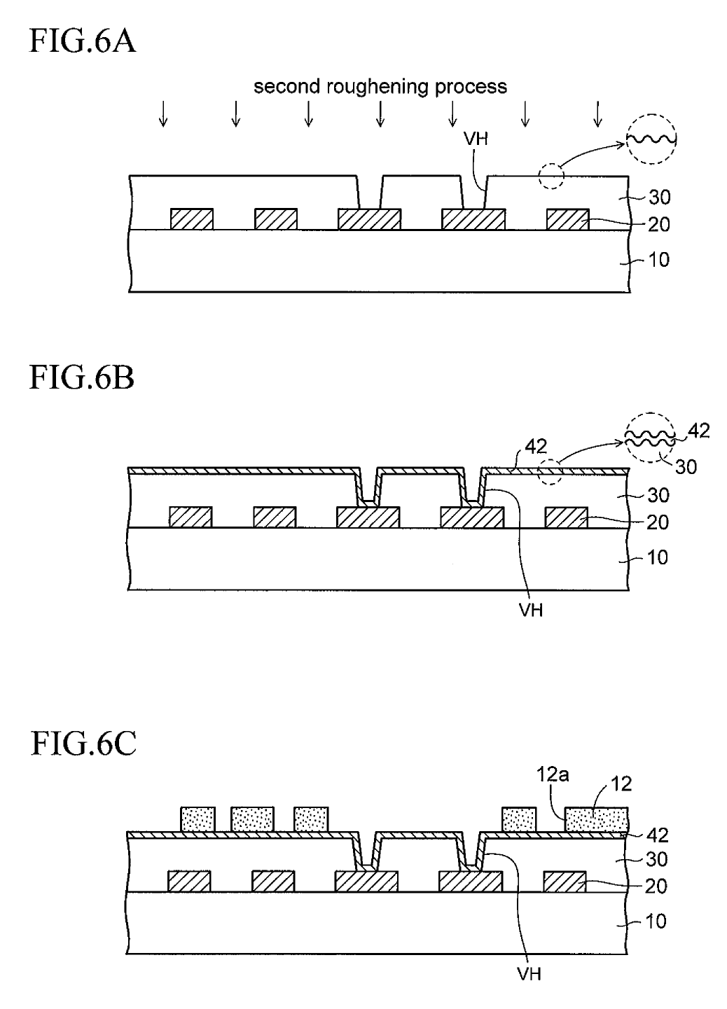

Then, as shown in FIG. 6A, unevenness (concave-convex surface) is formed on the surface of the interlayer insulating layer 30 by processing the interlayer insulating layer 30 by means of the second plasma, and the surface is roughened (second roughening process) (fragmental enlarged view). At this time, the desmear process has already been applied to the inside of the via holes VH by the first plasma process. Therefore, conditions of the plasma process can be adjusted without regard for the desmear process of the via holes VH such that the surface of the interlayer insulating layer 30 is set to a desired roughness. Preferably, a surface roughness (Ra) of the interlayer insulating layer 30 is set to 10 to 100 nm.

Not only the first plasma process but also the second plasma process is applied to the inside of the via holes VH. In this case, the problem is not caused particularly because side surfaces of the via holes VH and the first wiring layer 20 located at a bottom portion of the via holes VH are only roughened further.

As the gas used in the second plasma process (the second roughening process), like the first plasma process, any gas selected from a group consisting of a gas containing fluorine atoms such as CF₄, or the like, a gas containing chlorine atoms such as Cl₂, or the like, a gas containing bromine atoms such as HBr, or the like, a rare gas such as He, Ar, Xe, or the like, O₂, H₂O, H₂, N₂, and NH₃, or a mixed gas prepared by combining two gases or more selected from above group is used.

Similarly, as an example of the preferred gas, a mixed gas prepared by adding O₂, N₂, or the like to CF₄ is employed. Similarly, as the plasma process system, the anisotropic dry etching (RIE, or the like) may be employed, or the isotropic dry etching may be employed.

The surface of the interlayer insulating layer 30 can be set to a predetermined surface roughness by adjusting the kind of the gas and flow rate of the gas, chamber pressure, RF power, processing time, etc. in the dry etching equipment. Therefore, in the present embodiment, excessive unevenness is not formed on the surface of the interlayer insulating layer 30 unlike the prior art, and the surface of the interlayer insulating layer 30 is shaped into the roughened surface whose roughness is adjusted to a predetermined surface roughness that is suitable for the formation of the fine wiring layers. Therefore, as described later, the second wiring layers whose line width is fine in accordance with a design specification can be formed on the interlayer insulating layer 30 with good adhesion.

Otherwise, the surface roughening of the interlayer insulating layer 30 may be executed by UV (ultraviolet ray) irradiation, in addition to the above plasma process. For example, the surface of the interlayer insulating layer 30 is reformed by irradiating a UV ray (main wavelength: 253.7 nm) in a state that the interlayer insulating layer 30 is dipped in a TiO₂ suspended solution. Thus, the roughened surface that is equivalent to that obtained by the plasma process can be obtained.

Otherwise, the surface of the interlayer insulating layer 30 may be roughened by the wet etching process using a permanganate-based solution, or the like, like the above-mentioned desmear step (first roughening process step) of the via holes VH.

In this manner, the plasma process, the wet etching process, or the UV irradiation can be employed in the second roughening process step. Also, preferably the second roughening process step is set to the conditions that a roughening power applied to the interlayer insulating layer 30 is made weaker than that in the first roughening process step (desmear process).

In the present embodiment, a surface roughness (Ra) of the interlayer insulating layer 30 and a surface roughness (Ra) of the side surface of the via holes VH can be set to an optimum value independently respectively. When reliability of the via connection and further miniaturization of the wiring layer should be taken into consideration, it is preferable that the surface roughness (Ra) of the interlayer insulating layer 30 is set lower than the surface roughness (Ra) of the side surface of the via holes VH.

Next, a method of forming the second wiring layer on the interlayer insulating layer 30 by the semi-additive process will be explained hereunder. As shown in FIG. 6B, first, a seed layer 42 made of copper, or the like is formed on the inner surfaces of the via holes VH and the interlayer insulating layer 30. The seed layer 42 is formed by the electroless plating or the sputter method.

As described above, the surface of the interlayer insulating layer 30 is roughened adequately (surface roughness (Ra): 10 to 100 nm), and thus the seed layer 42 is formed on the interlayer insulating layer 30 with good adhesion by the anchor effect (fragmental enlarged view of FIG. 6B).

Then, as shown in FIG. 6C, a plating resist 12 in which opening portions 12a are formed in portions where the second wiring layer is arranged respectively is formed on the seed layer 42. The plating resist 12 is formed by pasting a dry film resist or coating a liquid resist, and then patterning the resist by means of the photolithography (exposure/development).

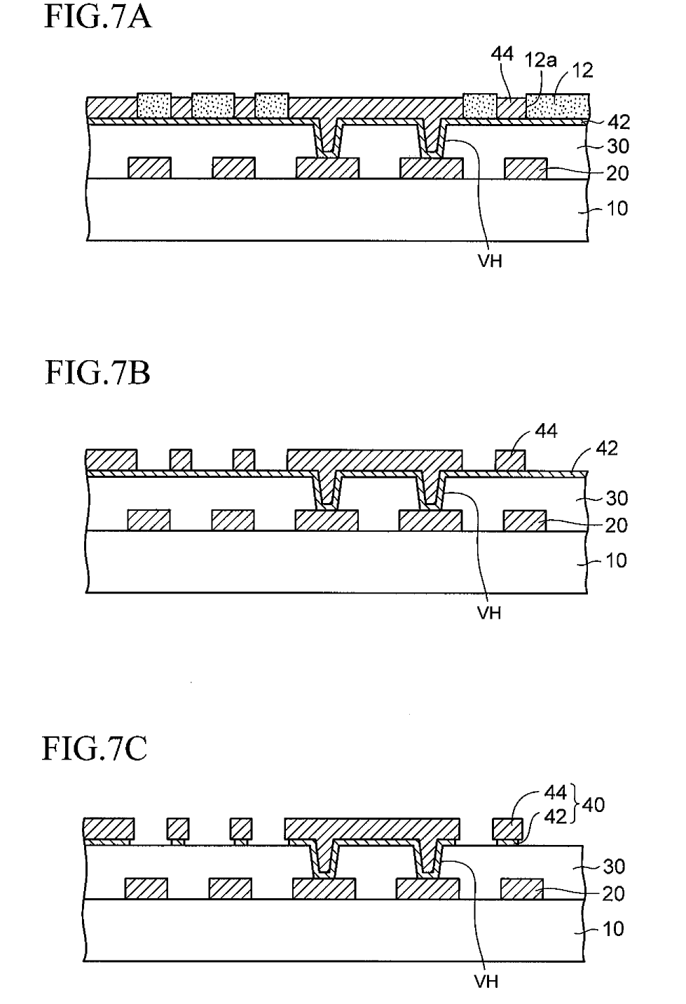

Then, as shown in FIG. 7A, a metal plating layer 44 made of copper, or the like is formed in from the via holes VH to the opening portions 12a in the plating resist 12, by the electroplating utilizing the seed layer 42 as a plating power feeding path. Then, as shown in FIG. 7B, the seed layer 42 is exposed by removing the plating resist 12.

Then, as shown in FIG. 7C, the seed layer 42 is etched while using the metal plating layer 44 as a mask. Accordingly, a second wiring layer 40 composed of the seed layer 42 and the metal plating layer 44 is formed on the interlayer insulating layer 30.

In the present embodiment, the desmear process (first roughening process) is applied to the inside of the via holes VH by the first plasma process in a state that the interlayer insulating layer 30 is protected by the protection layer 36 (first roughening process), and then after the protection layer 36 is removed, the surface of the interlayer insulating layer 30 is roughened by the second plasma process (second roughening process). That is, the desmear process of the via holes VH and the surface roughening of the interlayer insulating layer 30 are processed independently by the different plasma process.

For this reason, such a situation can be avoided that unevenness of the surface of the interlayer insulating layer 30 is set larger than necessary, and the surface of the interlayer insulating layer 30 can be set to a desired surface roughness (surface roughness (Ra): 10 to 100 nm). Therefore, an amount of overetching in the etching step of the seed layer 42 in the semi-additive process can be reduced smaller than the prior art. This is because a residue of the seed layer 42 is hard to occur as unevenness of the surface of the interlayer insulating layer 30 becomes smaller.

As a result, even though a design rule in which the line:space of the second wiring layer 40 is 15:15 μm or less is applied, the second wiring layer 40 can be formed to have the line width within a design specification and also the pattern jump (pattern disappearance) is not caused. Also, since the surface roughness (Ra) of the interlayer insulating layer 30 is set to 10 to 100 nm and the surface is roughened adequately, enough adhesion of the second wiring layer 40 can be obtained by the anchor effect.

In addition, the desmear process is applied sufficiently to the inside of the via holes VH by the plasma process. Therefore, satisfactory reliability of the via connection between the first wiring layer 20 and the second wiring layer 40 via the via holes VH can be obtained.

In this way, in the present embodiment, the desmear process of the via holes VH and the surface roughening of the interlayer insulating layer 30 are executed by the separate step respectively. Therefore, the desmear process of the via holes VH can be sufficiently performed, and the surface of the interlayer insulating layer 30 can be adjusted to a desired roughness and be roughened.

As a result, the miniaturization of the wiring layer formed by the semi-additive process can be achieved. Also, the sufficient adhesion of the wiring layer can be ensured, and satisfactory reliability of the via connection can be obtained.

The n-layered (n is an integer in excess of 2) multilayer wiring layer can be formed freely by repeating a series of steps from the step of forming the first wiring layer 20 to the step of forming the second wiring layer 40.

The present invention is particularly useful in forming the fine wiring layers by the semi-additive process with good yield. In this case, the present invention may be applied to various wiring forming methods such as the subtractive process, the full-additive process, and the like, in addition to the semi-additive process. In such case, adhesion of the wiring layers and reliability of the via connection can be ensured satisfactorily.

As an example constituting the wiring substrate, although not particularly illustrated, through electrodes (through hole plating layers, or the like) are provided in the substrate 10, and the wiring layer being connected mutually via the through electrodes is formed on both surface sides of the substrate 10 respectively. Then, a semiconductor chip is mounted on one surface side of the substrate 10, and external connection terminals are provided in the other surface side.

In the present embodiment, the fine wiring layer can be formed with good yield. Therefore, the wiring substrate for mounting a high-performance semiconductor chip can be manufactured easily.

### Second Embodiment

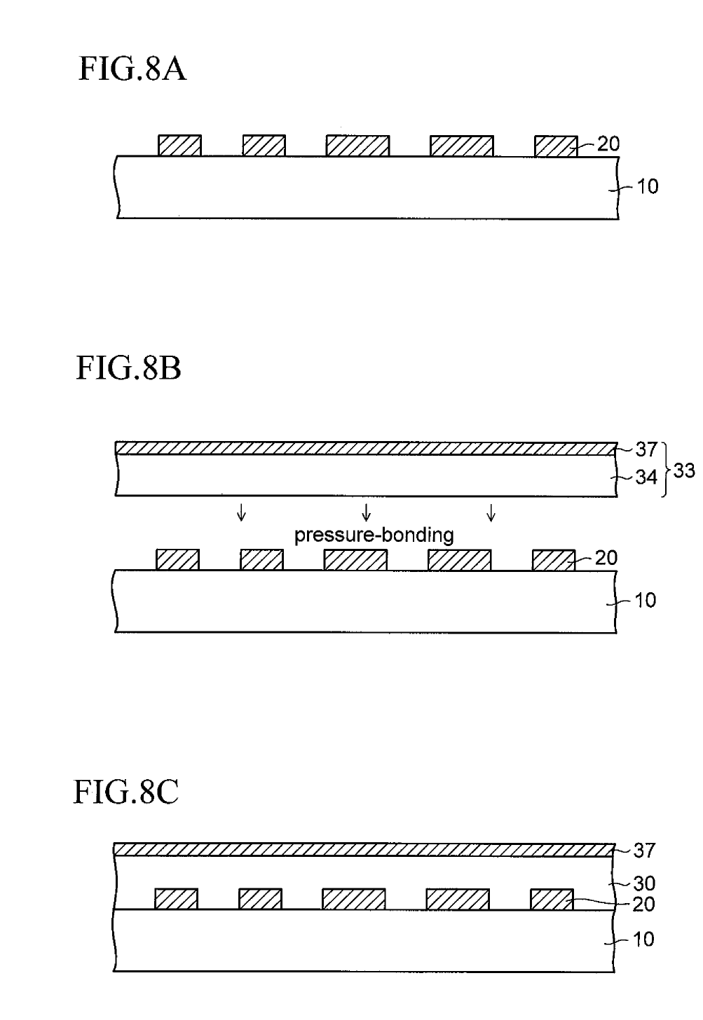

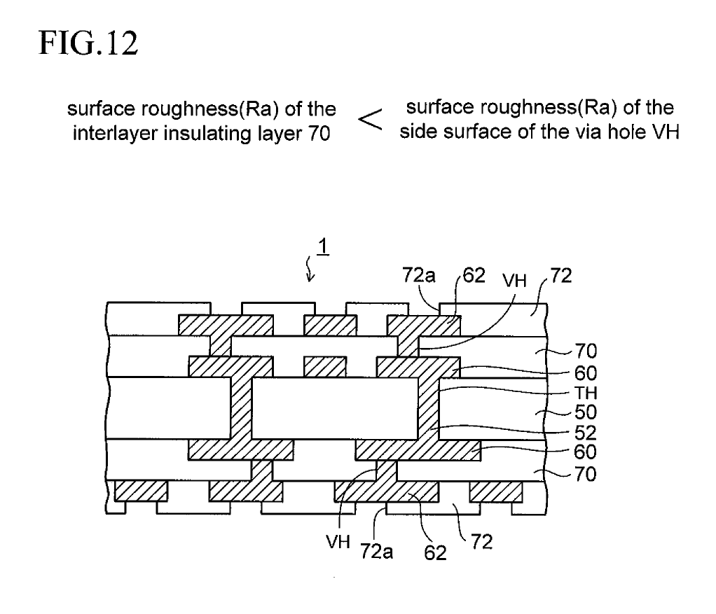

FIGS. 8A to 8C, FIGS. 9A to 9C, FIGS. 10A to 10C, and FIGS. 11A and 11B are sectional views showing a method of manufacturing a wiring substrate according to a second embodiment of the present invention, and FIG. 12 is a sectional view showing an example of the wiring substrate according to the same.

A difference of the second embodiment from the first embodiment resides in that the second roughening step (FIG. 6A) of roughening the surface of the interlayer insulating layer 30 in the first embodiment is omitted. In the second embodiment, detailed explanation of the same steps as those in the first embodiment will be omitted.

In the method of manufacturing the wiring substrate according to the second embodiment, like the first embodiment, as shown in FIG. 8A, first, the first wiring layer 20 made of copper, or the like and shaped into the pattern is formed on the substrate 10.

Then, as shown in FIG. 8B, a film with metal layer 33 in which a metal layer 37 (protection layer) is provided on the resin film 34 is prepared. As the resin film 34, preferably an epoxy resin film in which fillers such as silica, or the like are dispersed with the content percentage of 30 to 70 wt %, or the like should be employed. Also, as the metal layer 37, a metal layer such as a copper layer, or the like may be formed on the resin film 34 by the vapor deposition, or the like, otherwise a metallic foil such as a copper foil, an aluminum foil, or the like may be adhered onto the resin film 34.

Then, the first wiring layer 20 is covered with the resin film 34 by thermal pressure-bonding the surface of the resin film 34 of the film with metal layer 33 onto the substrate 10. Then, as shown in FIG. 8C, the film with metal layer 33 is cured by applying a heat treatment under the conditions that a temperature is 180° C. and a processing time is 30 min, and thus the interlayer insulating layer 30 is obtained. Accordingly, the first wiring layer 20 is covered with the interlayer insulating layer 30, and the metal layer 37 is formed on the interlayer insulating layer 30.

Like the first embodiment, the metal layer 37 is provided so as to protect the interlayer insulating layer 30 such that, in applying the desmear process to the inside of the via holes by using the plasma, unnecessary unevenness is not produced on the surface of the interlayer insulating layer 30.

In the above mode, as the preferred example, the film with metal layer 33 is pressure-bonded onto the first wiring layer 20. In this case, a stacked body in which the interlayer insulating layer 30 and the metal layer 37 are stacked sequentially may be formed on the first wiring layer 20. That is, the resin film 34 may be pressure-bonded onto the first wiring layer 20 and then the metallic foil may be adhered. Otherwise, the resin film 34 may be pressure-bonded onto the first wiring layer 20, and then the metal layer may be formed by the vapor deposition, or the like. In this case also, the resin film 34 is thermally treated in a state that this film is covered with the metal layer 37, and thus constitutes the interlayer insulating layer 30.

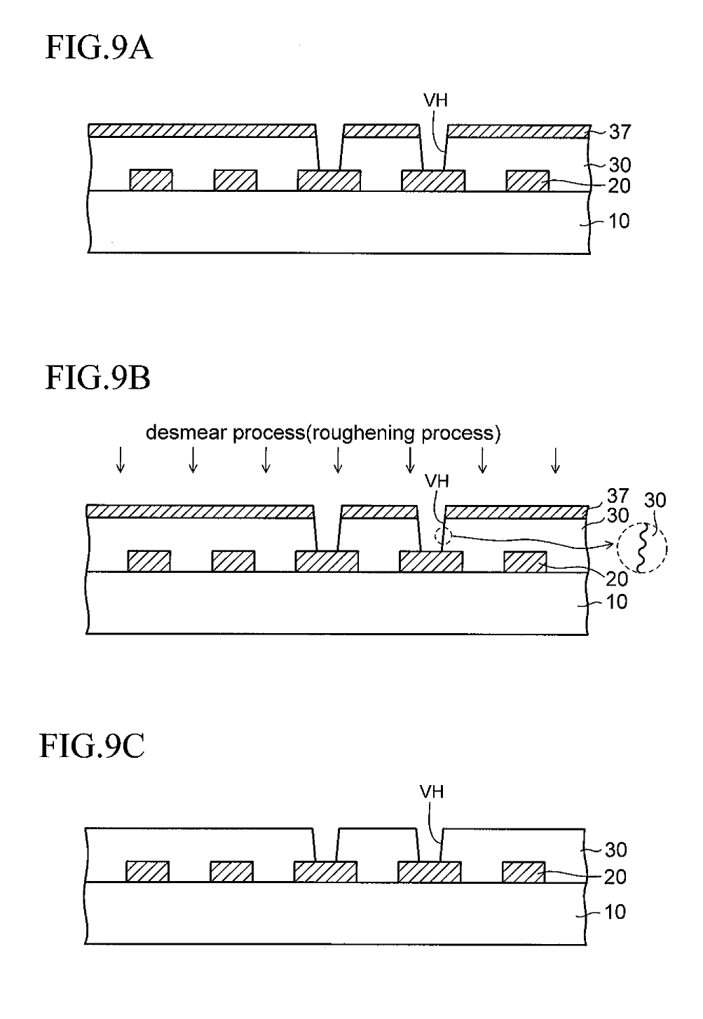

Then, as shown in FIG. 9A, the metal layer 37 and the interlayer insulating layer 30 are processed by the laser, or the like, and thus the via holes VH having a depth that reaches the first wiring layer 20 are formed. Then, like the first embodiment, as shown in FIG. 9B, the desmear process (roughening process) is applied to the inside of the via holes VH while using the wiring substrate as a mask.

Like the first embodiment, as the desmear process, the plasma process or the wet etching process using a permanganate-based solution, or the like may be employed. Accordingly, a resin smear remaining in the via holes VH is cleaned. At the same time, side surfaces of the via holes VH are roughened (fragmental enlarged view of FIG. 9B). A surface roughness (Ra) of the side surface of the via holes VH is set to 100 to 600 nm (preferably about 300 nm).

In the present embodiment, the desmear process is applied to the inside of the via holes VH while using the metal layer 37 as a mask, and thus the surface of the interlayer insulating layer 30 is protected from the desmear process by the metal layer 37. Therefore, even though the desmear process is applied sufficiently to the inside of the via holes VH, the surface of the interlayer insulating layer 30 is not affected at all.

Then, as shown in FIG. 9C, the upper surface of the interlayer insulating layer 30 is exposed by removing the metal layer 37. When the metallic foil is employed as the metal layer 37, such metallic foil is removed by peeling the peripheral portion thereof. Also, when the metal layer is formed by the vapor deposition, or the like, such metal layer is removed by the wet etching. Here, a film thickness (about 0.5 to 1 μm) of the metal layer 37 is set considerably thinner than a film thickness (30 to 40 μm) of the first wiring layer 20. Therefore, even when both the first wiring layer 20 and the metal layer 37 are formed of copper, the problem is not particularly caused.

In the second embodiment, the roughening process step of the surface of the interlayer insulating layer 30 can be omitted, unlike the first embodiment. At this time, a surface roughness (Ra) of the interlayer insulating layer 30 after the metal layer 37 is removed is 10 to 100 nm (preferably 10 to 50 nm).

In the second embodiment, as described above, the resin film 34 into which the fillers are dispersed with the content percentage of 30 to 70 wt % is cured by applying the thermal treatment in a state that such resin film 34 is covered with the metal layer 37. By employing such approach, the surface of the interlayer insulating layer 30 is in a condition having good adhesion to the wiring layer unless the surface roughening of the interlayer insulating layer 30 is particularly executed.

In this manner, in the second embodiment, a surface roughness (Ra: 10 to 100 nm) of the interlayer insulating layer 30 is set smaller than a surface roughness (Ra: 100 to 600 nm) of the side surface of the via holes VH provided in the interlayer insulating layer 30.

In this case, in the second embodiment, in order to getting the high adhesion to the wiring layer without roughening the surface of the interlayer insulating layer 30, the metal layer 37 is adequate as the protection layer which covers the resin film 34. As the protection layer, the PET film, the resist, or the like can be employed. In such case, there is such as tendency that the adhesion to the wiring layer is lowered rather than the case where the metal layer 37 is employed. This is because a surface condition of the interlayer insulating layer 30 is changed depending upon the material of the protection layer.

Also, since the interlayer insulating layer 30 is formed by using the resin film 34 into which the fillers are dispersed, a coefficient of thermal expansion (CTE) is rendered close between the interlayer insulating layer 30 and the first wiring layer 20. Therefore, such approach is convenient from the viewpoint of improving reliability of the multilayer wiring.

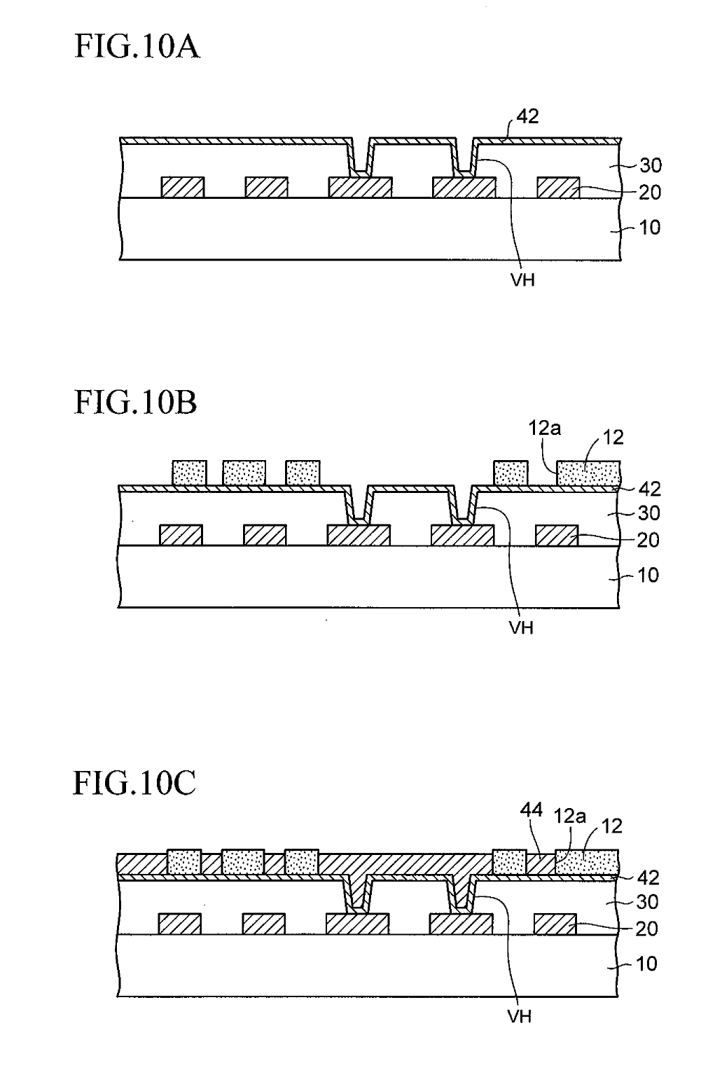

Then, like the first embodiment, the second wiring layer is formed on the interlayer insulating layer 30 by the semi-additive process. First, as shown in FIG. 10A, the seed layer 42 made of copper, or the like is formed on the side surface of the via holes VH and the interlayer insulating layer 30.

In the second embodiment, since the surface roughening of the interlayer insulating layer 30 is not applied but its surface keeps a good adhesion condition to the wiring layer, the seed layer 42 is formed on the interlayer insulating layer 30 to have sufficient adhesion. However, in the second embodiment, since the surface roughening of the interlayer insulating layer 30 is omitted, the adhesion produced due to the anchor effect tends to become small rather than the first embodiment.

Therefore, in the second embodiment, it is preferable that the seed layer 42 should be formed by the sputter method. When the sputter method is employed, the seed layer 42 is formed on the interlayer insulating layer 30 that the above roughening process is not applied, with a sufficient adhesion strength.

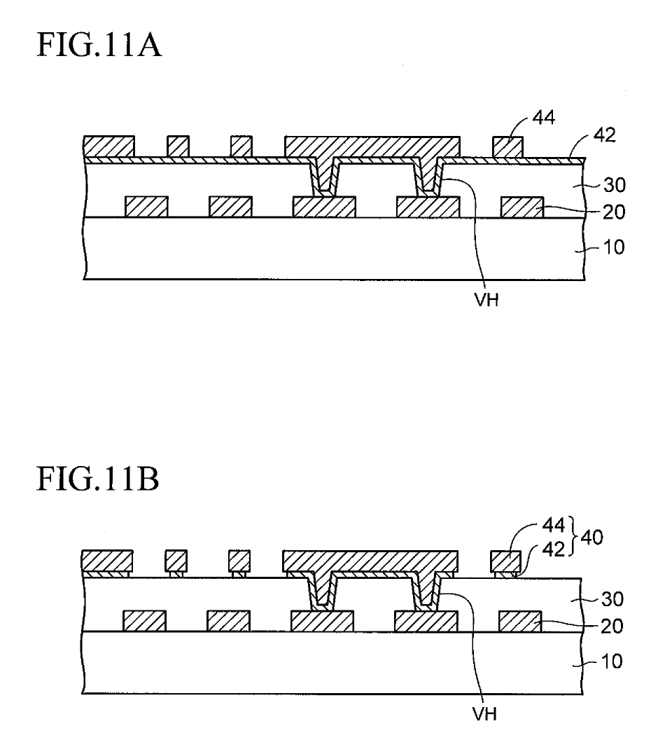

Then, as shown in FIG. 10B, the plating resist 12 in which the opening portions 12a are formed in portions where the second wiring layer is arranged respectively is formed on the seed layer 42. Then, as shown in FIG. 10C, the metal plating layer 44 made of copper, or the like is formed in from the via holes VH to the opening portions 12a in the plating resist 12 by the electroplating utilizing the seed layer 42 as a plating power feeding path. Then, as shown in FIG. 11A, the seed layer 42 is exposed by removing the plating resist 12.

Then, as shown in FIG. 11B, the seed layer 42 is etched while using the metal plating layer 44 as a mask. Accordingly, the second wiring layer 40 composed of the seed layer 42 and the metal plating layer 44 is formed on the interlayer insulating layer 30.

In the second embodiment, since the surface roughening of the interlayer insulating layer 30 is not executed, a surface roughness (Ra) of the interlayer insulating layer 30 can be set smaller than that in the first embodiment. Therefore, an amount of overetching of the seed layer 42 in the etching step by the semi-additive process can be reduced rather than the first embodiment. As a result, the second wiring layer 40 that is finer than that in the first embodiment can be formed with good yield.

Also, the surface of the interlayer insulating layer 30 can be brought into a good adhesion condition to the wiring layer while setting a surface roughness (Ra) of the interlayer insulating layer 30 small. Therefore, the second wiring layer 40 with good adhesion can be formed on the interlayer insulating layer 30.

Further, the desmear process can be applied sufficiently to the via holes VH. Therefore, satisfactory reliability of the via connection between the first wiring layer 20 and the second wiring layer 40 via the via holes can be obtained.

Next, the wiring substrate of the second embodiment will be explained hereunder. FIG. 12 is a sectional view showing an example of the wiring substrate in the second embodiment of the present invention. As shown in FIG. 12, in a wiring substrate 1 of the second embodiment, through holes TH are provided in a core substrate 50 and also a through electrode 52 is filled in the through holes TH respectively.

A first wiring layer 60 connected mutually via the through electrodes 52 is formed on both surface sides of the core substrate 50 respectively. Otherwise, the first wiring layer 60 formed on both surface sides respectively may be connected mutually via the through hole plating layers provided on the inner walls of the through holes TH, and then remaining holes in the through holes TH may be filled with a resin.

Also, an interlayer insulating layer 70 for covering the first wiring layer 60 is formed on both surface sides of the core substrate 50 respectively. The via holes VH reaching the first wiring layer 60 are provided in the interlayer insulating layer 70 on both surface sides of the core substrate 50 respectively. The side surfaces of the via holes VH are roughened by the above method, and its surface roughness (Ra) is set to 100 to 600 nm (preferably about 300 nm).

Also, the roughening process is not applied to the surface of the interlayer insulating layer 30, and its surface roughness (Ra) is set to 10 to 100 nm (preferably 10 to 50 nm). For example, the interlayer insulating layer 30 is formed of an epoxy resin in which the fillers such as silica, or the like are dispersed with the content percentage of 30 to 70 wt %.

A second wiring layer 62 connected electrically to the first wiring layer 60 via the via hole VH is formed on the interlayer insulating layer 70 on both surface sides of the core substrate 50 respectively. Also, a solder resist 72 in which opening portions 72a are provided on connection portions of the second wiring layer 62 is formed on both surface sides of the core substrate 50. A contact layer (not shown) made of a Ni/Au plating layer, or the like is formed on the connection portions of the second wiring layer 62 respectively.

Also, a semiconductor chip is mounted on the connection portions of the second wiring layer 62 on one surface side of the core substrate 50, while external connection terminals are provided on the connection portions of the second wiring layer 62 on the other surface side. In this case, the number of stacked wiring layers formed on both surface sides of the core substrate 50 can be set arbitrarily.

In the wiring substrate 1 of the second embodiment, a surface roughness (Ra) of the surface of the interlayer insulating layer 70 on which the second wiring layer 62 is formed is set lower than a surface roughness Ra of the side surface of the via hole VH provided in the interlayer insulating layer 70.

In the second embodiment, the roughening process is not applied to the surface of the interlayer insulating layer 70, but the surface of the interlayer insulating layer 70 can be in a good adhesion condition to the wiring layer. That is, even though a surface roughness (Ra) of the interlayer insulating layer 30 is set small like 10 to 50 nm, sufficient adhesion of the second wiring layer 62 can be obtained. As a result, the fine second wiring layer 62 having the good adhesion can be formed with good yield.

Also, since the side surface of the via holes VH is roughened sufficiently, satisfactory reliability of the via connection between the first wiring layer 60 and the second wiring layer 62 via the via hole VH can be obtained. Also, reliability of the via connection can be ensured even when multi-stage stacked vias are formed.

In this manner, in the wiring substrate 1 of the second embodiment, the fine second wiring layer 62 (the line:space is 15:15 μm or less) can be formed on the smooth interlayer insulating layer 30 (surface roughness (Ra): 100 nm or less) with good adhesion. As a result, the wiring substrate whose electric characteristics are excellent can be constructed, and can be employed as the mounting substrate for mounting the high-performance semiconductor chip.

Here, in the present invention, a surface roughness (Ra) of the interlayer insulating layer may be set lower than a surface roughness (Ra) of the side surface of the via hole. The present invention can be applied to various wiring substrates such as the coreless wiring substrate with no core substrate, and the like, in addition to the wiring substrate 1 illustrated in FIG. 12.

What is claimed is:

1. A method of manufacturing a wiring substrate, comprising:
a step of forming a first wiring layer on an underlying layer;
a step of forming a stacked body in which a protection layer is provided on an insulating layer, on the first wiring layer;
a step of forming a via hole reaching the first wiring layer, by processing the protection layer and the insulating layer;
a first roughening step of roughening a side surface of the via hole, by applying a desmear process to an inside of the via hole while using the protection layer as a mask;
a step of exposing a surface of the insulating layer by removing the protection layer; and
a step of forming a second wiring layer, which is connected to the first wiring layer via the via hole, on the insulating layer.

2. A method of manufacturing a wiring substrate according to claim 1, after the step of exposing the surface of the insulating layer, further comprising:
a second roughening step of roughening the surface of the insulating layer.

3. A method of manufacturing a wiring substrate according to claim 2, wherein a surface roughness (Ra) of the insulating layer is set lower than a surface roughness (Ra) of the side surface of the via hole.

4. A method of manufacturing a wiring substrate according to claim 2, wherein the second roughening step of roughening the surface of the insulating layer is a step of processing by a plasma, a step of processing by a wet etching, or a step of irradiating UV onto the surface of the insulating layer.

5. A method of manufacturing a wiring substrate according to claim 1, wherein, after the step of exposing the surface of the insulating layer, the second wiring layer is formed on the insulating layer, without roughening the surface of the insulating layer.

6. A method of manufacturing a wiring substrate according to claim 5, wherein the insulating layer is formed of a resin in which fillers are dispersed with a content percentage of 30 to 70 wt %, and the protection layer is formed of a metal layer, and
the step of forming the stacked body includes curing the resin which is covered with the metal layer by thermal treatment.

7. A method of manufacturing a wiring substrate according to claim 1, wherein the step of forming the second wiring layer includes the steps of,
forming a seed layer in the via hole and on the insulating layer,
forming a resist in which an opening portion is provided in a portion where the second wiring layer is arranged, on the seed layer,
forming a metal plating layer in the via hole and the opening portion of the resist by an electroplating utilizing the seed layer as a plating power feeding path,
removing the resist, and
obtaining the second wiring layer composed of the seed layer and the metal plating layer, by etching the seed layer while using the metal plating layer as a mask.

8. A method of manufacturing a wiring substrate according to claim 1, wherein the step of forming the stacked body includes pressure-bonding a film with protection layer in which the protection layer is formed on a resin film, onto the first wiring layer.

9. A method of manufacturing a wiring substrate according to claim 1, wherein the protection layer is any one of a PET film, a resist, and a metal layer.

10. A method of manufacturing a wiring substrate according to claim 5, wherein a surface roughness (Ra) of the insulating layer is 10 to 100 nm, and a surface roughness (Ra) of the side surface of the via hole is 100 to 600 nm.

11. A method of manufacturing a wiring substrate according to claim 1, wherein, in a design rule of the second wiring layer, a line:space is set to 15:15 μm or less.

12. A method of manufacturing a wiring substrate according to claim 4, wherein the process by the plasma is executed by an anisotropic etching or an isotropic etching in a dry etching equipment.

13. A method of manufacturing a wiring substrate according to claim 4, wherein a gas used in the plasma is a gas selected from a group consisting of a gas containing fluorine atoms, a rare gas, oxygen, water, hydrogen, nitrogen, and ammonia, or a mixed gas prepared by combining two gases or more selected from the group.

14. A wiring substrate, comprising:
a first wiring layer;
an insulating layer formed on the first wiring layer;
a via hole provided in the insulating layer to reach the first wiring layer; and
a second wiring layer formed on the insulating layer and connected to the first wiring layer via the via hole;
wherein a surface roughness (Ra) of the insulating layer is set lower than a surface roughness (Ra) of a side surface of the via hole.

15. A wiring substrate according to claim 14, wherein the surface roughness (Ra) of the insulating layer is 10 to 100 nm, and the surface roughness (Ra) of the side surface of the via hole is 100 to 600 nm.

16. A wiring substrate according to claim 14, wherein the insulating layer is formed of a resin in which fillers are dispersed with a content percentage of 30 to 70 wt %.
